(19) United States
(12) Patent Application Publication
(10) Pub. No.: US 2020/0403379 A1
(43) Pub. Date: Dec. 24, 2020

(54) VERTICAL CAVITY SURFACE EMITTING LASER DIODE (VCSEL) WITH MULTIPLE CURRENT CONFINEMENT LAYERS

(71) Applicant: VISUAL PHOTONICS EPITAXY CO., LTD., Taoyuan City (TW)

(72) Inventors: Chao-Hsing Huang, Taoyuan City (TW); Yu-Chung Chin, Taoyuan City (TW); Van-Truong Dai, Taoyuan City (TW)

(21) Appl. No.: 16/906,067

(22) Filed: Jun. 19, 2020

(30) Foreign Application Priority Data
Jun. 21, 2019 (TW) 108121853

(51) Int. Cl. H01S 5/183

(52) U.S. Cl. CPC H01S 5/18397; H01S 5/18311

(57) ABSTRACT

Provided is a vertical cavity surface emitting laser diode (VCSEL) with multiple current confinement layers. A tunnel junction is generally required between two active layers to enable current to flow from one to another active layer. However, the tunnel junction will cause the current to spread in one active layer to become serious. As a result, the current in another active layer is difficult to be confined to the required area. Therefore, a current confinement layer with carrier and optical confinement functions is provided between two active layers such that the carrier and optical confinement of the active layers above and below the current confinement layer can be improved, thereby improving the performance of VCSEL. Compared with the existing VCSEL, the VCSEL with multiple current confinement layers can significantly improve the optical output power, slope efficiency and power conversion efficiency (PCE) of the VCSEL.

### CROSS-REFERENCE TO RELATED APPLICATION

This application claims priority to Taiwanese Application Serial No. 108121853, filed on Jun. 21, 2019. The entirety of the above-mentioned patent application is hereby incorporated by reference herein and made a part of this specification.

### TECHNICAL FIELD

The technical field relates to a vertical cavity surface emitting layer diode (VCSEL) with multiple current confinement layers, especially a VCSEL with a current confinement layer/current confinement layers inside an active region, wherein the active region includes multiple active layers.

### BACKGROUND

Laser light sources such as vertical cavity surface emitting layer diodes (VCSELs) are now commonly used as light sources for 3D sensing or optical communications. If the optical output power and power conversion efficiency of a VCSEL can be further improved, the 3D sensing or optical communications can save more power or reduce the chip area to reduce cost. In addition, the application of the VCSEL can also be extended to light detection and ranging (LiDAR), Virtual Reality (VR), Augmented Reality (AR), Direct Time-of-Flight (dTOF) sensors or other applications.

The main feature of a VCSEL is that it emits light generally perpendicular to its wafer surface. Generally, epitaxial growth methods such as metal organic chemical vapor deposition (MOCVD) or molecular beam epitaxy (MBE) can be used to form an epitaxial structure having a multi-layer structure on the substrate.

The VCSEL includes an active region and distributed Bragg reflectors (DBR) respectively disposed above and below the active region. These is a laser resonant cavity between two DBRs, which can generate light of a specific wavelength in the active region and reflect back and forth in the resonant cavity to generate gain amplification such that laser light is generated. According to the direction of laser light emission, the VCSEL can be categorized into a top-emitting VCSEL and a bottom-emitting VCSEL. When the total reflectivity of the upper DBR layer is less than that of the lower DBR layer, the VCSEL is called a top-emitting VCSEL. When the total reflectivity of the upper DBR layer is greater than that of the lower DBR layer, the VCSEL is called a bottom-emitting VCSEL.

The optical output power of the VCSEL is related to the carrier density (current density) in the active region. Therefore, one method to increase the carrier density in the active region is to form a current confinement layer above the active region. The current confinement layer has a current confinement optical aperture (OA). After a current passes through the current confinement OA, the current will be confined to one area in the active region to increase the carrier density in the active region, thereby improving the power conversion efficiency (PCE) of the VCSEL.

However, although a single active layer combined with a single current confinement layer can improve the PCE of the VCSEL, the detection distance of the sensing device using the VCSEL is still be limited and the power loss is still large. The PCE and optical output power of the VCSEL required by future applications, such as LiDAR, AR, VR, dTOF, handheld devices or portable electronic devices, are still not achieved.

As such, it is necessary to provide a VCSEL including multiple active layers such that the carrier confinement of each active layer in the VCSEL can be further improved, and the optical output power and PCE of the VCSEL is significantly improved.

### SUMMARY

In theory, when a current confinement layer with a current confinement optical aperture (OA) is provided above an active region, and when the active region includes an active layer, the optical output power of a VCSEL is assumed to be one time. Under the same conditions, when two, three or N active layers are disposed inside the active region, the optical output power of the VCSEL should be increased approximately 2 times, 3 times or N times, and the power conversion efficiency (PCE) of the VCSEL should also be increased.

However, in fact, when the number of active layers increases, the optical output power of the VCSEL does not increase as expected, and the PCE does not even increase but decreases significantly. In addition, the resistance of the current confinement layer is higher. Accordingly, the more current confinement layers are, the larger the VCSEL's resistance will become, and the larger resistance will easily cause the PCE of the VCSEL to become lower.

In the case where the active region has multiple active layers (i.e., a multi-junction VCSEL), in order to allow current to pass through each active layers, a tunnel junction is generally required between every two adjacent active layers such that the current can pass through other active layers to realize the carrier recycling mechanism in the multi-junction VCSEL. When the current confinement layer is disposed above the active region, the OA of the current confinement layer can contribute to the current confinement. However, the current will gradually spread after passing through the OA. When the current passes through the high conductivity tunnel junction, the current spread will become severe and serious. Although the tunnel junction enables current to flow into other active layers, the current is more divergent, resulting in poor carrier confinement of other active layers. Consequently, although the number of active layers has increased, the optical output power of the multi-junction VCSEL has been slightly improved. However, the PCE of the multi-junction VCSEL has dropped significantly due to the poor carrier confinement of some active layers.

As a result, the above problem must be overcome. One technical means of the present disclosure are to dispose the current confinement layer(s) in the active region and to dispose the current confinement layer(s) between two active layers. It is assumed that the current flows through the current confinement layer (above the active region), the second active layer, the tunnel junction, the current confinement layer (within the active region) and the first active layer in order from top to bottom.

It is worth noting that by disposing the current confinement layer(s) in the active region, not only can the current confinement and/or optical confinement of the first active layer be improved, but also the current and/or optical confinement of the second active layer may be improved.

In the prior art, after the current passes through the current confinement optical aperture (outside the active region), the current begins to gradually diverge, and the current spread will become severe and serious when the current passes through the tunnel junction.

Unlike the prior art, after disposing the current confinement layer(s) in the active region, the current will gradually change from divergence to convergence before the current passes through the OA(s) of the current confinement layer(s) (inside the active region). Thus, the current flowing through the second active layer and the tunnel junction becomes less divergent, and the carrier confinement of the second active layer becomes better. After the current passes through the OA(s) of the current confinement layer(s) (within the active region), the current will be converged and confined to the area of the first active layer corresponding to the OA(s). As such, the carrier density of the area of the first active layer corresponding to the OA(s) is relatively increased, thereby improving the carrier confinement of the first active layer and improving the optical output power and PCE of the multi-junction VCSEL.

By disposing the current confinement layer between two active layers, the carrier confinement effect of the current confinement layer can act on the second active layer above the current confinement layer and/or the first active layer below the current confinement layer. As a consequence, not only can the carrier confinement of the first active layer be improved, but also the carrier confinement of the second active layer can be further improved. Therefore, the optical output power or slope efficiency of the multi-junction VCSEL can be increased significantly, and the PCE of the multi-junction VCSEL can also be significantly improved as the number of active layers is increase.

In principle, the VCSEL is not limited to a top-emitting VCSEL or a bottom-emitting VCSEL, i.e., a top-emitting VCSEL or a bottom-emitting VCSEL with multiple active layers. After the current confinement layer is provided between two active layers, the slope efficiency, the optical output power or the PCE of the top-emitting or bottom-emitting multi-junction VCSEL can be significantly improved.

According to an exemplary embodiment of the present disclosure, a VCSEL is provided. The VCSEL includes a substrate and a multi-layer structure on the substrate. The multi-layer structure includes an active region and a plurality of current confinement layers. The active region includes a plurality of active layers. A tunnel junction is provided between two active layers. The plurality of current confinement layers at least includes a first current confinement layer and a second current confinement layer. The first current confinement layer at least has a first OA, and the second current confinement layer at least has a second OA. The first OA and the second OA are uninsulated portions of each current confinement layer. One of the first OA and the second OA is disposed outside the active region, and the other of the first OA and the second OA is disposed inside the active region. The tunnel junction is between the first current confinement layer and the second current confinement layer.

In some embodiments, the areas of the first OA and the second OA are unequal or nearly equal.

In some embodiments, if the areas of the first OA and the second OA are not less than 30 μm², the areas of the first OA and the second OA may be unequal, or even nearly equal. The areas of the first OA and the second OA may also be more than 40 μm² or 50 μm². Furthermore, the ratio of the area of the first OA to the area of the second OA is X, wherein 0.3≤X≤1. When the ratio X is not equal to 1, the smaller area between the first OA and the second OA is the numerator of the ratio, and the larger area between both thereof is the denominator of the ratio.

According to another specific embodiment, the active region of the present disclosure includes three or more active layers. The plurality of current confinement layers of the present disclosure further includes a third current confinement layer. The third current confinement layer also has a third OA. The third OA is also the uninsulated portion of the third current confinement layer. One of the first OA, the second OA and the third OA is disposed outside the active region, and another of the first OA, the second OA and the third OA is disposed inside the active region, and the other of the first OA, the second OA and the third OA is disposed inside or outside the active region The tunnel junction is positioned between the first OA and the second OA or between the second OA and the third OA.

In some embodiments, the areas of two of the first OA, the second OA and the third OA are unequal or approximately equal.

In some embodiments, when the areas of two of or the area of each of the first OA, the second OA and the third OA are/is more than 30 μm², the areas of two thereof or the area of each thereof may be unequal, or may even be nearly equal. The areas of two thereof or the area of each thereof may also be more than 40 μm² or 50 μm².

Furthermore, two of the first, second and third OAs have a ratio X, where 0.3≤X≤1. When the OA area ratio X is not equal to 1, the smaller area among two thereof is the numerator of the ratio.

According to the exemplary embodiments described above, the PCE, the slope efficiency or optical output power of the multi-junction VCSEL have been significantly improved. Since the optical output power is increased, the sensing distance of the sensing device using the multi-junction VCSEL can be greatly increased, or the chip size of the multi-junction VCSEL can be reduced to help reduce costs. Since the PCE of the multi-junction VCSEL is improved, the multi-junction VCSEL itself consumes less power such that it can save more power of the sensing device or extend battery life of the sensing device. The increase of sensing distance of the sensing device using the VCSEL accelerates and diversifies the development of applications such as LiDAR, AR, VR, dTOF, etc.

### BRIEF DESCRIPTION OF THE DRAWINGS

FIG. 1a is a schematic diagram showing that one of two current confinement layers is disposed inside the active region according to one embodiment of the present disclosure, wherein the optical aperture (OA) of the current confinement layer outside the active region is smaller than that of the current confinement layer inside the active region.

FIG. 1b is a schematic diagram showing that one of two current confinement layers is disposed inside the active region according to one embodiment of the present disclosure, wherein the OA of the current confinement layer outside the active region is greater than that of the current confinement layer inside the active region.

FIG. 1c is a schematic diagram showing that one of two current confinement layers is disposed inside the active region according to one embodiment of the present disclosure, wherein the OAs of the two current confinement layers are approximately equal or close to each other.

FIG. 1d is a detailed schematic diagram showing a possible structure of the active region of FIG. 1a.

FIG. 2 is a schematic diagram showing that the number of active layers is greater than the number of current confinement layers according to one embodiment of the present disclosure.

FIG. 3a shows a schematic diagram of a VCSEL including three current confinement layers and two active layers according to one embodiment of the present disclosure, wherein the OAs of the three current confinement layers are not equal.

FIG. 3b shows a schematic diagram of a VCSEL including three current confinement layers and two active layers, wherein the OAs of the three current confinement layers are approximately equal or close to each other.

FIG. 3c is a detailed schematic diagram showing a possible structure of the active region of FIG. 3a.

FIG. 4a shows a schematic diagram of a VCSEL including three current confinement layers and three active layers according to one embodiment of the present disclosure, wherein the OAs of the three current confinement layers are not equal.

FIG. 4b shows a schematic diagram of a VCSEL including three current confinement layers and three active layers according to one embodiment of the present disclosure, wherein the areas of the second OA and the third OA are approximately equal or close to each other, and the first OA outside the active region is smaller than the second OA or the third OA inside the active region.

FIG. 4c shows a schematic diagram of a VCSEL including three current confinement layers and three active layers according to one embodiment of the present disclosure, wherein the OAs of the three current confinement layers are approximately equal or close to each other.

FIG. 5a shows a schematic diagram of a VCSEL including four current confinement layers and three active layers according to one embodiment of the present disclosure, wherein the relationship among the first OA to the fourth OA is from small to large.

FIG. 5b shows a schematic diagram of a VCSEL including four current confinement layers and three active layers according to one embodiment of the present disclosure, wherein the relationship among the first OA to the fourth OA is from large to small.

FIG. 6a shows a schematic diagram of a VCSEL including five current confinement layers and five active layers according to one embodiment of the present disclosure, wherein the OAs of the five current confinement layers are not equal.

FIG. 6b shows a schematic diagram of a VCSEL including five current confinement layers and five active layers according to one embodiment of the present disclosure, wherein the OAs of four current confinement layers inside the active region are approximately equal or close to each other, and the OA of the current confinement layer outside the active region is smaller than the OAs of the current confinement layers inside the active region.

FIG. 6c shows a schematic diagram of a VCSEL including five current confinement layers and five active layers according to one embodiment of the present disclosure, wherein the fourth OA and the fifth OA are larger than the second OA and the third OA, and the second OA and the third OA are larger than the first OA.

FIG. 7 is the photoelectric characteristic of the VCSEL in which the areas of OAs of two current confinement layers at different ratios are provided and the photoelectric characteristic of the prior art, wherein the VCSEL is a top-emitting VCSEL.

FIG. 8 shows a comparison of the photoelectric characteristic of the VCSEL in which three active layers with different numbers of current confinement layers.

FIG. 9 shows the photoelectric characteristic of the VCSEL in which the areas of OAs of two current confinement layers at different ratios are provided and the photoelectric characteristic of the prior art, wherein the VCSEL is a bottom-emitting VCSEL.

### DESCRIPTION OF THE EMBODIMENTS

The embodiment of the present disclosure is described in detail below with reference to the drawings and element symbols, such that persons skilled in the art is able to implement the present application after understanding the specification of the present disclosure.

Specific examples of components and arrangements are described below to simplify the present disclosure. These are, of course, merely examples and they are not intended to limit the scope of the present disclosure. In the present disclosure, for example, when a layer formed above or on another layer, it may include an exemplary embodiment in which the layer is in direct contact with the another layer, or it may include an exemplary embodiment in which other devices or epitaxial layers are formed between thereof, such that the layer is not in direct contact with the another layer. In addition, repeated reference numerals and/or notations may be used in different embodiments, these repetitions are only used to describe some embodiments simply and clearly, and do not represent a specific relationship between the different embodiments and/or structures discussed.

Further, spatially relative terms, such as “underlying,” “below,” “lower,” “overlying,” “above,” “upper” and the like, may be used herein for ease of description to describe one device or feature's relationship to another device(s) or feature(s) as illustrated in the figures and/or drawings. The spatially relative terms are intended to encompass different orientations of the device in use or operation in addition to the orientation depicted in the figures and/or drawings.

Moreover, certain terminology has been used to describe embodiments of the present disclosure. For example, the terms “one embodiment,” “an embodiment,” and “some embodiments” mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment.

Furthermore, the particular features, structures or characteristics may be combined in any suitable manner in one or more embodiments of the present disclosure. Further, for the terms “including”, “having”, “with”, “wherein” or the foregoing transformations used herein, these terms are similar to the term “comprising” to include corresponding features.

In addition, a “layer” may be a single layer or a plurality of layers; and “a portion” of an epitaxial layer may be one layer of the epitaxial layer or a plurality of adjacent layers.

In the prior art, the laser diode can be optionally provided with a buffer layer according to actual needs, and in some embodiments, the materials of the buffer and the substrate may be the same. Whether the buffer is provided is not substantially related to the technical characteristics to be described in the following embodiments and the effects to be provided. Accordingly, for the sake of a brief explanation, the following embodiments are only described with a laser diode having a buffer layer, and no further description is given to a laser without a buffer layer; that is, the following embodiments can also be applied by replacing a laser diode without a buffer.

A vertical cavity surface emitting laser diode (VCSEL) is provided in the present disclosure. The typical manufacturing method of a VCSEL is to epitaxially grow a multi-layer structure on a substrate, and the finished product of a VCSEL is not necessary to have a substrate. That is, the VCSEL can retain the substrate or remove the substrate. The multi-layer structure includes an active region, and the active region includes one or a plurality of active layers. If the active region includes a plurality of active layers, a tunnel junction is arranged between every two adjacent active layers.

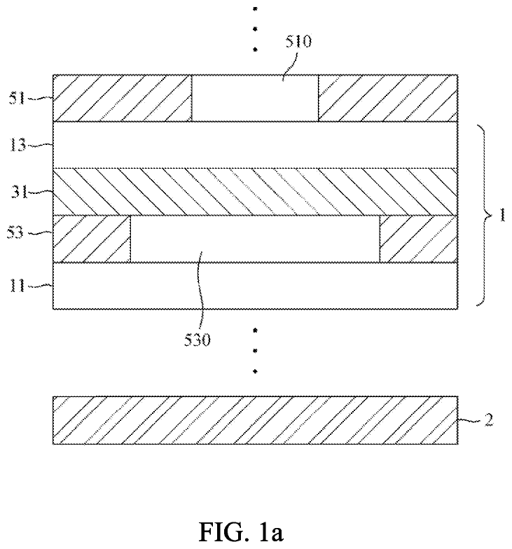

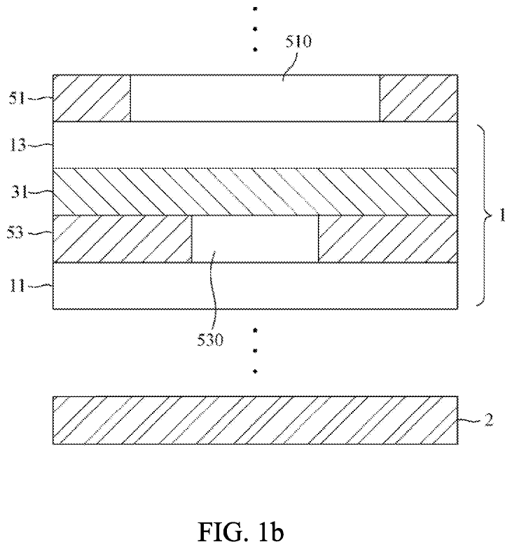

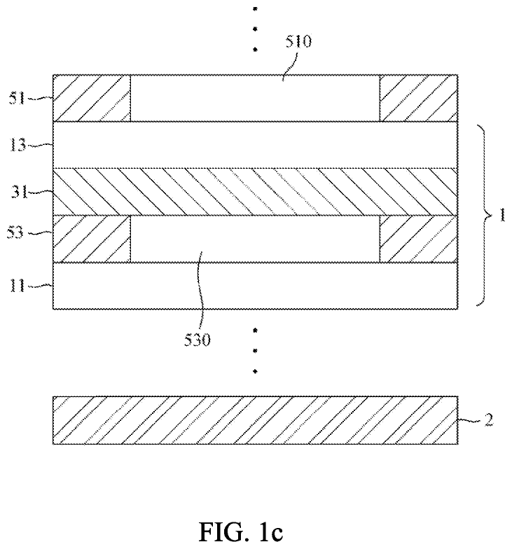

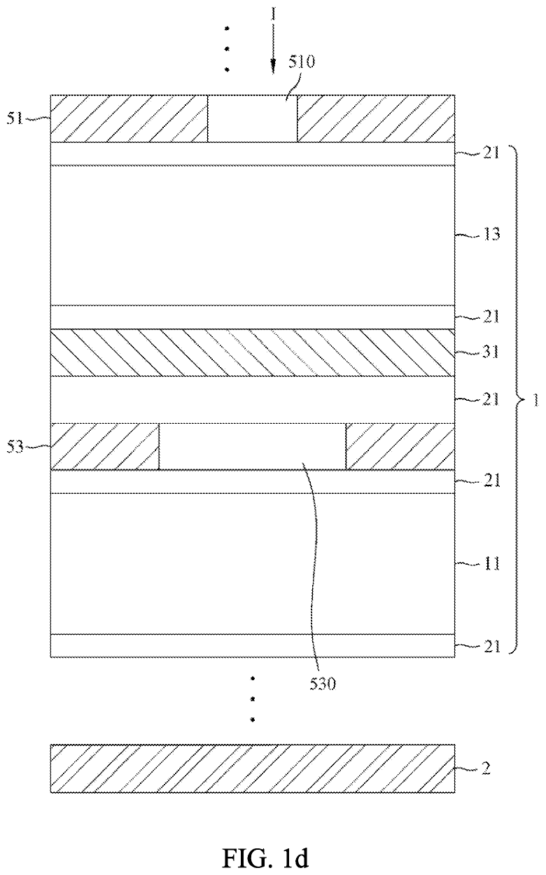

Each embodiment of the present disclosure is to provide two or more current confinement layers in the multi-layer structure. Each current confinement layer has at least one optical aperture (OA). The OA is the uninsulated portion of each current confinement layer, while the insulated portion of each current confinement layer (as shown by the diagonal lines of the current confinement layer 51 of FIG. 1a) should be understood as the portion with a high resistance of the current confinement layer.

The number of current confinement layers may be three, four, five or more layers. In different embodiments, the disposition or combination of current confinement layers will be different. Therefore, in order to distinguishing the position of each current confinement layer, in the case of two current confinement layers, one of the current confinement layers is called the first current confinement layer, and the other one is called the second current confinement layer. In the case of three or more current confinement layers, they are called the first current confinement layer, the second current confinement layer, the third current confinement layer, and so on. Similarly, in order to distinguish the position of each active layer of the multiple active layers in the VCSEL, the active layers of the multiple active layers are called the first active layer, the second active layer, the third active layer . . . to the Nth active layer, and so on.

In order to simplify the drawings, Most of the drawings only show epitaxial layers such as active layers, tunnel junctions and current confinement layers, etc., the other epitaxial layers such as upper DBR layers, lower DBR layers, spacer layers, ohmic contact layers, etc. are not displayed even if these epitaxial layers are a necessary or preferred structure of a VCSEL. The spacer layer is generally formed above and/or below the active layer, current confinement layer, tunnel junction or other epitaxial layers. The spacer layer may be selectively disposed according to actual needs, and the material, material composition, thickness, doping and doping concentration of each spacer layer may also be adjusted appropriately in accordance with actual needs.

The following uses some representative embodiments to explain how two or more current confinement layers are specifically arranged in a VCSEL.

### Embodiment 1

In terms of the main structure shown in FIGS. 1a, 1b and 1c, the first current confinement layer 51 with the first OA 510 is disposed on the active region 1. The tunnel junction 31 and the second current confinement layer 53 with the second OA 530 are disposed between the first active layer 11 and the second active layer 13 in the active region 1. The tunnel junction 31 is between the first current confinement layer 51 and the second current confinement layer 53.

According to the structure of FIG. 1a, since the tunnel junction 31, the second current confinement layer 53 and the first active layer 11 are sequentially under the second active layer 13, in this configuration, when current flows from the first OA 510 and into the first active layer 11 through the second OA 530. The epitaxial layer above the first current confinement layer 51 is mainly composed of a P-type epitaxial layer. If the epitaxial layer above the first current confinement layer 51 further includes an N-type epitaxial layer (not shown), the N-type epitaxial layer and the first current confinement layer 51 can be connected in series with the tunnel junction or form an indirect contact through the tunnel junction.

In terms of OA areas (i.e., opening areas), the OA area of the first OA is not equal to the OA area of the second OA, as shown in FIGS. 1a and 1b. As shown in FIG. 1c, when the OA areas of the first OA 510 and the second OA 530 are sufficiently large, the OA areas of the first OA 510 and the second OA 530 may be substantially equal or close to each other.

FIG. 1d is the detailed structure of FIG. 1a. In FIG. 1d, the spacer layer 21 is provided above and below the active layers 11, 13, the current confinement layers 53(51) and the tunnel junction 31. Current I mainly passes through the first OA 510 for carrier confinement and/or optical confinement, the second active layer 13 for emitting light, the tunnel junction 31 for carrier recycling or connecting two active layers, the second OA 530 for carrier confinement and/or optical confinement, and the first active layer 11 for emitting light.

After the current I enters the second active layer 13 from the first OA 510, the current I flowing through the second active layer 13 and the tunnel junction 31 becomes less spreading, such that the carrier confinement of the second active layer 13 becomes better. After the current I passes through the second OA 530 of the second current confinement layer 53, the current I is more easily confined to the area of the first active layer 11 corresponding to the second OA 530, such that the carrier and/or optical confinement of the first active layer 11 and the second active layer 13 can be significantly improved, thereby improving the optical output power, slope efficiency, or power conversion efficiency (PCE) of the VCSEL.

By disposing the second current confinement layer between two active layers, the carrier confinement effect of the second current confinement layer can act on the second active layer and the first active layer above and below the second current confinement layer. In this way, not only can the carrier confinement and/or optical confinement of the first active layer be improved, but also the carrier confinement and/or optical confinement of the second active layer can be further improved. As such, the optical output power of the VCSEL can be significantly increased as the number of active layers is increased, and slope efficiency or the PCE of the VCSEL can also be significantly improved as the number of active layers is increased.

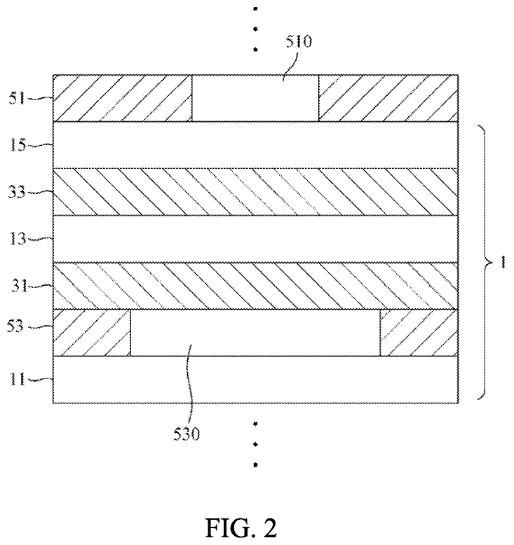

In some embodiments, the number of current confinement layers may be less than the number of active layers. As shown in FIG. 2, the number of current confinement layers may be two layers. The number of active layers in the active region may be three layers, but not limited thereto. The number of active layers may be four or more layers. If the optical output power, slope efficiency or PCE of the VCSEL needs to be further improved, the number of current confinement layers may be the same as that of the active layers. The number of current confinement layers may also be more than the number of active layers. For example, the number of current confinement layers may be more than the number of active layers by one more layer or more than two layers, but the total resistance of all current confinement layers cannot be too large, otherwise it may affect the performance or PCE of the VCSEL.

Another factor that determines the resistance of the current confinement layer is the area of the OA of the current confinement layer. In principle, the OA areas of two OAs or the OA areas of the OAs may be unequal. However, if the OA areas of two OAs or the OA areas of the OAs are large enough, since the resistance is small, the OA areas of two OAs or the OA areas of the OAs may still be approximately equal or close to each other.

In FIGS. 1a and 1b, the OA areas of the first OA and the second OA are not equal. The ratio of the OA area of the first OA to the OA area of the second OA may be between 0.1 and 10 (excluding the ratio of 1). The total resistance of the current confinement layers is not too large so as not to significantly affect the performance or PCE of the VCSEL. Preferably, the ratio of the OA area of the first OA to the OA area of the second OA may be between 0.2 and 5, between 0.3 and 3.3, between 0.5 and 2, between 0.54 and 1.85 or between 0.6 and 1.6. In addition to maintaining better carrier confinement and/or optical confinement, the total resistance of two current confinement layers is relatively small so as to help improve the performance or PCE of the VCSEL. The specific ratio of the area of the first OA to the area of the second OA is 0.5, 0.6, 0.7, 0.8, 0.9, 1.0, 1.1, 1.2, 1.3, 1.4, 1.5, 1.6, 1.7, 1.8, 1.9 or 2.0.

In the case where the areas of the first OA and the second OA are sufficiently large, since the resistance of the first current confinement layer and the second current confinement layer are relatively small, the total resistance of both thereof is not easily too large. Accordingly, the areas of the first OA and the second OA may be approximately equal or even equal. For example, if the areas of the first OA and the second OA are not less than 30 μm², the area of the first OA may be approximately equal to, nearly equal, or even exactly equal to that of the second OA. In some embodiments, the smaller area of each current confinement layer may also be greater than 40 μm² or 50 μm².

According to the previous paragraph, if the total resistance of current confinement layers can be appropriately reduced, it is easy to maintain or improve the PCE of the VCSEL, and the first active layer and the second active layer may also have better carrier confinement and optical confinement, thereby improving the performance, slope efficiency or PCE of the VCSEL. The VCSEL may be a top-emitting VCSEL or a bottom-emitting VCSEL.

In the case where the areas of both the first OA and the second OA are sufficiently large, preferably, the ratio of the area of the first OA to the area of the second OA is X, where 0.3≤X≤1. Therefore, in one case, the areas of the first OA and the second OA are approximately equal or close to each other; that is, the ratio of the area of the first OA to the area of the second OA is close to or may be exactly 1 (X≈1 or X=1). In the other case, when the areas of the first OA and the second OA are different, the ratio of the area of the first OA to the area of the second OA is greater than or equal to 0.3 and less than 1 (0.3≤X<1). The smaller area between the first OA and the second OA is the numerator of the ratio, and the larger area between both thereof is the denominator of the ratio.

### Embodiment 2

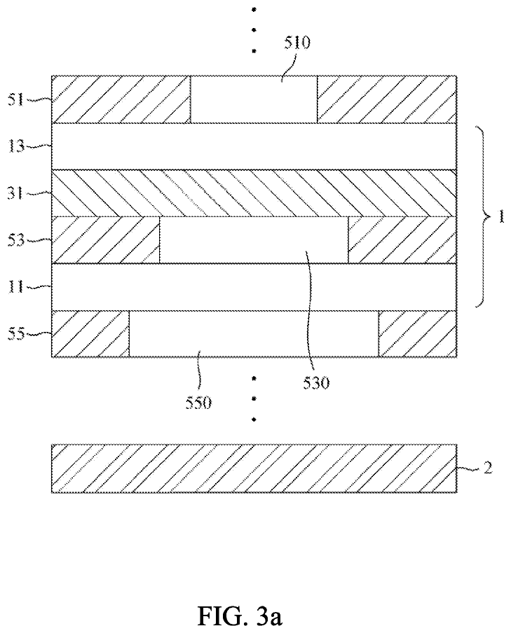

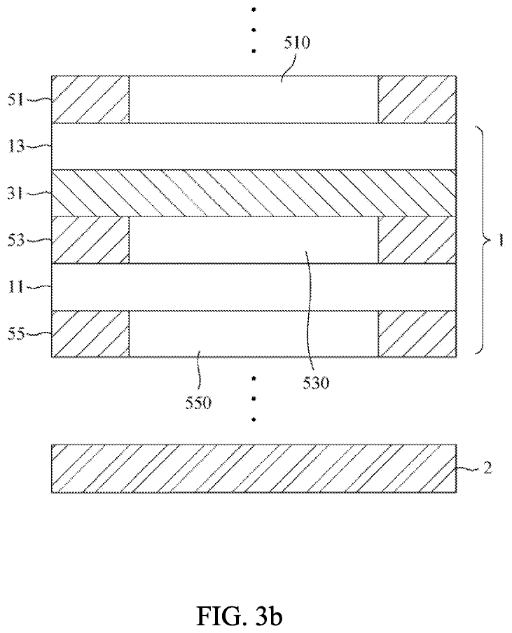

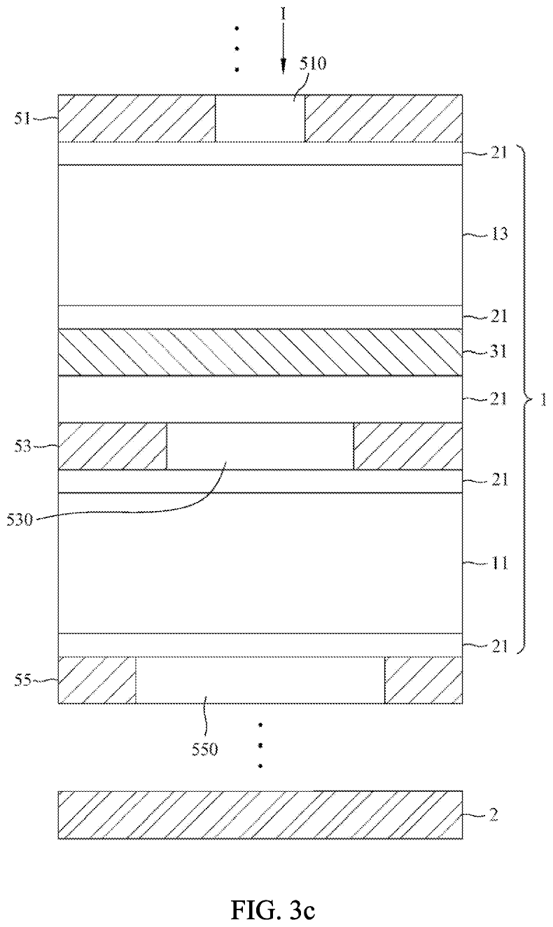

As shown in FIG. 3a, the VCSEL includes three current confinement layers 51, 53, 55 and two active layers 11, 13. The areas of the three current confinement layers 51, 53, 55 are not equal to each other, and the areas of the first, second and third OAs are a small area, a medium area and a large area, respectively. The structure shown in FIG. 3a is only an example. The areas of the first, second and third OAs may also be a large area, a medium area and a small area, respectively, may be a small area, a medium area and a medium area, respectively, or may be various other appropriate combinations. Preferably, the ratio of the area of the first OA to the area of the second OA, the ratio of the area of the second OA to the area of the third OA or the ratio of the area of the third OA to the first OA may be between 0.2 and 5, between 0.3 and 3.3, between 0.5 and 2, between 0.54 and 1.85 or between 0.6 and 1.6. The specific ratio thereof may be 0.5, 0.6, 0.7, 0.8, 0.9, 1.0, 1.1, 1.2, 1.3, 1.4, 1.5, 1.6, 1.7, 1.8, 1.9 or 2.0.

As long as the carrier confinement and/or optical confinement of the active layer as well as the PCE of the VCSEL are not significantly affected, the area of OA of the current confinement layer outside the active region 1 may be as large as possible, as shown in the third OA 550 of FIG. 3a. In the VCSEL provided with multiple current confinement layers, the total resistance of current confinement layers is less likely to be too large such that the performance of the VCSEL are also less likely to be affected.

### Embodiment 3

In the case where the VCSEL includes three current confinement layers or even more current confinement layers, if the areas of some OAs or all OAs are large enough, that is, the total resistance of the current confinement layers will not be too large, the areas of some OAs or all OAs may not be equal to each other, and two or each of some OAs or all OAs may also be approximately equal or close to each other.

Taking FIG. 3b as an example, if the smallest area among the first, second and third OAs is greater than 30 μm² (40 μm²/50 μm²), the areas thereof may even be equal to each other. In principle, as long as the total resistance of the current confinement layers does not significantly affect the PCE of the VCSEL, one or some of the current confinement layers may be less than 30 μm² (40 μm²/50 μm²).

Further, two of the first, second and third OAs have a ratio X, where 0.3≤X≤1. Accordingly, the areas thereof may be equivalent, that is, the ratio X is close to or may be exactly equal to 1 (X≈1 or X=1). When the areas of two thereof or all three OAs are different, the ratio X is greater than or equal to 0.3 and less than 1 (0.3≤X<1). In such case, the smaller area among two thereof is numerator of the ratio.

FIG. 3c is the detailed structure of FIG. 3a. In FIG. 3c, a spacer layer 21 is provided above and below the active layers 11, 13, the tunnel junction 31 and the current confinements 51, 53, 55, but FIG. 3c is only an example. Other modified or derived implementation structures may also be included in the present disclosure. The main structures in FIG. 3b and FIG. 3a are also the same. In FIG. 3b, the spacer layer may also be provided in the foregoing manner.

### Embodiment 4

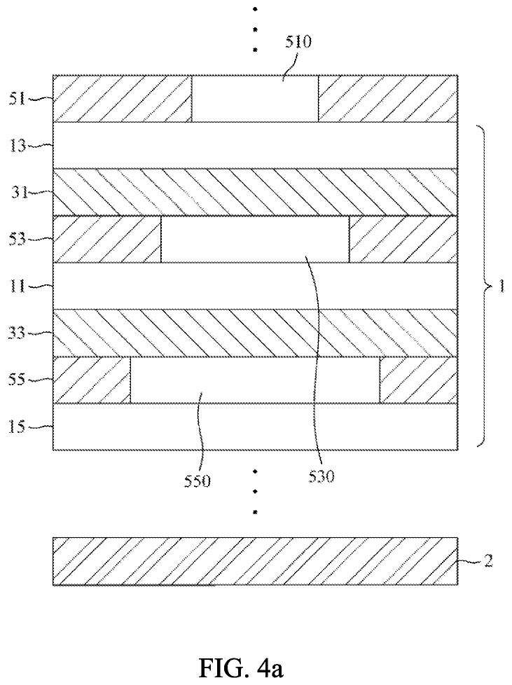

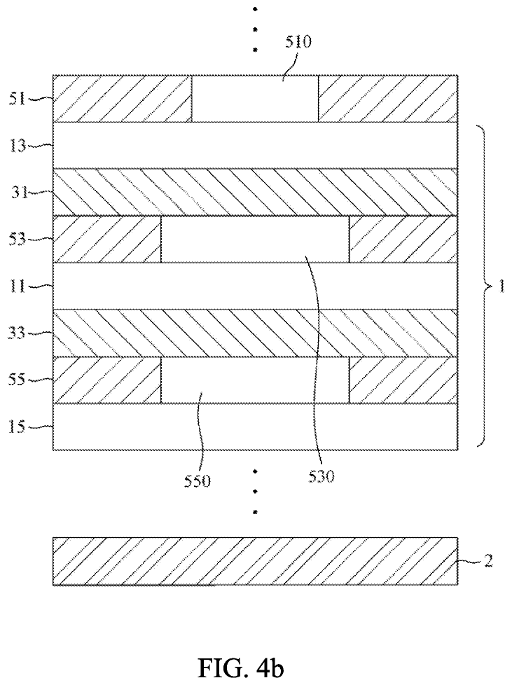

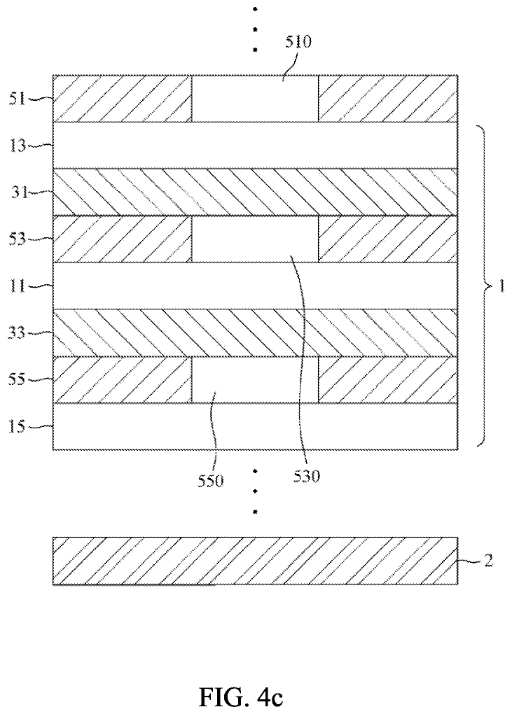

As shown in FIG. 4a, FIG. 4a is based on FIG. 3a, and further includes a third active layer 15 and a tunnel junction 33. The third active layer 15 is disposed below the first active layer 11, and a tunnel junction 33 and a third current confinement layer 55 are provided between the third active layer 15 and the first active layer 11. In addition, a tunnel junction 31 is disposed between the first current confinement layer 51 and the second current confinement layer 53, while the tunnel junction 33 is provided between the second current confinement layer 53 and the third current confinement layer 55.

In FIG. 4a, the areas of the first OA 510, the second OA 530 and the third OA 550 are a small area, a medium area and a large area, respectively. The structure shown in FIG. 4a is only an example. The areas of the first OA 510, the second OA 530 and the third OA 550 may also be a large area, a medium area and a small area, respectively, may be a small area, a large area and a medium area, or may be various other appropriate combinations. Alternatively, as shown in FIG. 4b, the area of the first OA 510 is small, and the areas of the second OA 530 and the third OA 550 are almost equal and larger than the area of the first OA 510. On the other hand, as shown in FIG. 4c, the areas of the first OA 510, the second OA 530 and the third OA 550 are approximately equal or equal.

A spacer or other epitaxial layers may further be provided above and/or below the active layer, current confinement layer or tunnel junction in FIGS. 4a-4c in accordance with actual needs.

### Embodiment 5

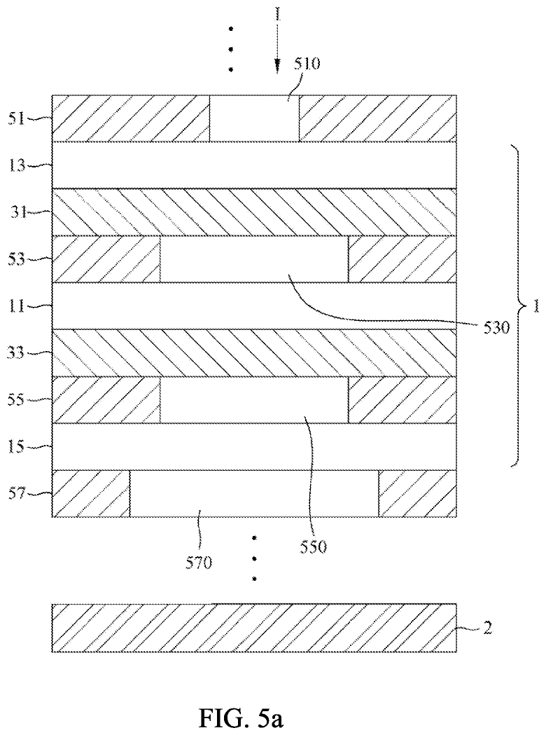

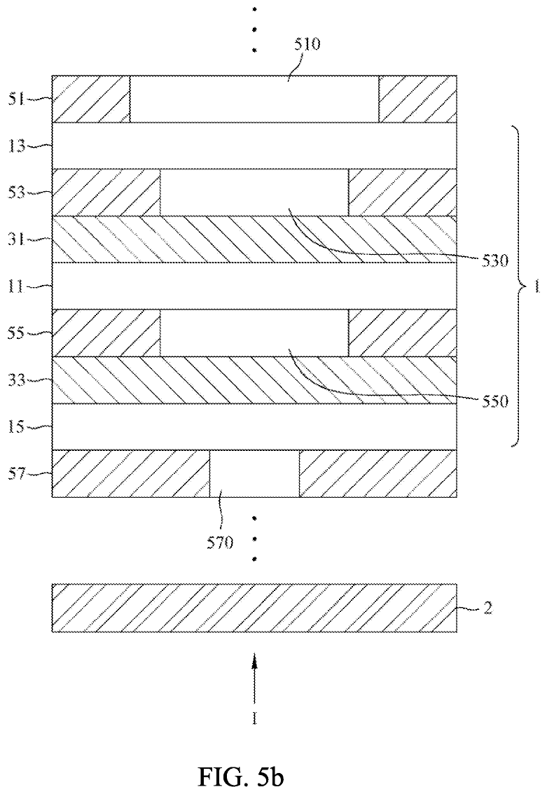

As shown in FIG. 5a, the VCSEL includes an active region 1 with three active layers 11, 13, 15, four current confinement layers 51, 53, 55, 57 and two tunnel junctions 31, 33. The first current confinement layer 51 and the fourth current confinement layer 57 are disposed above and below the active region 1. The tunnel junction 31 is provided between the first current confinement layer 51 and the second current confinement layer 53, and the tunnel junction 33 is provided between the second current confinement layer 53 and the third current confinement layer 55.

According to the arrangement relationship between the third current confinement layer 55 and the tunnel junction 33 of FIG. 5a, when current flows from the first OA 510, an epitaxial layer above the first current confinement layer 51 is mainly composed of a P-type epitaxial layer. If the epitaxial layer above the first current confinement layer 51 further includes an N-type epitaxial layer, a serial connection or indirect connection may be formed through a tunnel junction between the N-type epitaxial layer and the first current confinement layer 51.

As shown in FIG. 5b, the VCSEL includes an active region 1 with three active layers 11, 13, 15 and four current confinement layers 51, 53, 55, 57 and two tunnel junctions 31, 33. The first current confinement layer 51 and the fourth current confinement layer 57 are disposed above and below the active region 1. According to the arrangement relationship between the tunnel junction 33 and the third current confinement layer 55 or the arrangement relationship between the tunnel junction 31 and the second current confinement layer 53 of FIG. 5b, current flows from the fourth OA 570. An epitaxial layer below the fourth current confinement layer 57 is mainly composed of a P-type epitaxial layer. If the epitaxial layer below the fourth current confinement layer 57 further includes an N-type epitaxial layer, a serial connection or indirect connection may be formed through a tunnel junction between the N-type epitaxial layer and the fourth current confinement layer 57.

In a modified embodiment, the area of OA of the current confinement layer outside the active region 1 may be very large, as shown in the fourth current confinement layer 57 (below the active region 1) of FIG. 5a or the first current confinement layer 51 (above the active region 1) of FIG. 5b. In such case, the total resistance of each current confinement layer is less likely to be too large, and the performance of the VCSEL is less likely to be affected.

A spacer or other epitaxial layers may further be provided above and/or below the active layer, current confinement layer and/or tunnel junction layer in FIG. 5a or FIG. 5b according to actual needs.

### Embodiment 6

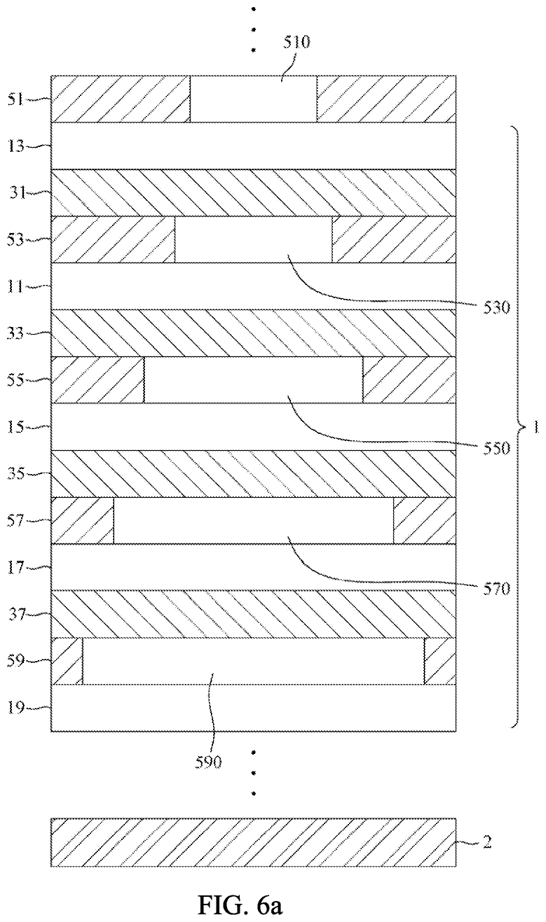

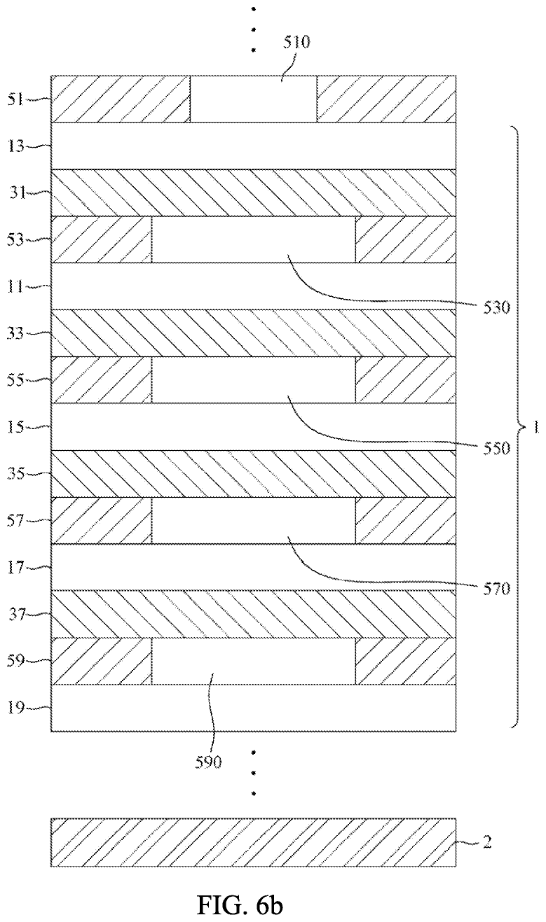

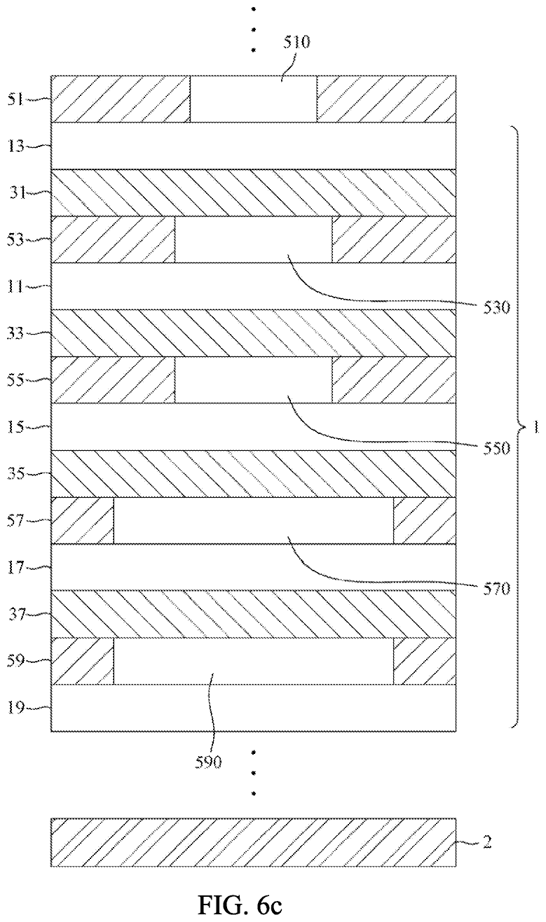

FIGS. 6a, 6b and 6c show a VCSEL including five current confinement layers and five active layers. In FIG. 6a, the areas of the first OA 510, the second OA 530, the third OA 550, the fourth OA 570 and the fifth OA 590 are not equal to each other. The area of the first OA 510 is the smallest and the area of the fifth OA 590 is the largest. The area of the second OA 530 is larger than that of the first OA 510, the area of the third OA 550 is larger than that of the second OA 530, and the area of the fourth OA 570 is larger than that of the third OA 550. The structure shown in FIG. 6a is only an example. The areas of the first OA to the fifth OA may be various other appropriate combinations.

In FIG. 6b, the area of the first OA 510 above the active region 1 is the smallest, and the areas of the second OA 530, the third OA 550, the fourth OA 570 and the fifth OA 590 in the active region 1 are approximately equal or close to each other. The structure shown in FIG. 6b is only an example. The areas of the first OA 510 through the fifth OA 590 may also be various other suitable combinations.

In FIG. 6c, the area of the first OA 510 is relatively smallest, the areas of the fourth OA 570 and the fifth OA 590 are relatively large, and the areas of the second OA 530 and the third OA 550 are larger than the area of the first OA 510 but smaller than the area of the fourth OA 570 or the fifth OA 590.

A spacer or other epitaxial layers may further be provided above and/or below the active layer, current confinement layer and/or tunnel junction layer or in FIGS. 6a-6c according to actual needs.

In the aforesaid embodiments, the OAs of the current confinement layers, such as the first OA 510, the second OA 530, the third OA 550, the fourth OA 570, the fifth OA 590, etc., are basically the portions of the current confinement layers that are not insulated. The insulation process may be appropriate insulation processes such as an oxidation process, an ion implantation process or an etching process. In principle, the insulation process is performed from the sides of the multi-layer structure to form the insulation portion of each current confinement layer. The size of the area of each OA can be determined by the oxidation process or the ion implantation process.

In general, the size of the OA is related to the parameters of the oxidation process, such as oxidation time or oxidation rate, etc. The oxidation rate is related to the material or material composition of each current confinement layer or the thickness of each current confinement layer. As such, if the current confinement layers need to form OAs of different sizes, different materials may be used for different current confinement layers, the same material may be used for different current confinement layers but the material composition are different, or the thicknesses of the current confinement layers are different.

In addition, the mesa type process or the non-planar type process may also be a factor that determines the size of an OA. In terms of mesa type process, the insulation process is carried out from the outer side of the mesa. If the mesa is probably narrow on the top and wide at the bottom (such as a trapezoid or ladder shape) or wide on the top and narrow at the bottom (not shown), even if the materials, material composition and thicknesses of current confinement layers are the same, that is, even under the same oxidation rate, the insulation portions of the current confinement layers will be almost the same, but the size of the OAs are different.

If the mesa is as shown in FIG. 1a, under the condition that the diameters of the upper or lower half of the mesa are approximately the same, if the areas of OAs of the current confinement layers are to be as consistent as possible, the materials, material composition and thicknesses of the current confinement layers can be the same. In this way, under the same oxidation rate, the areas of the current confinement layers may be more consistent.

For non-planar type process, multiple holes are formed in the multi-layer structure by wet etching or dry etching such that the holes are distributed in different positions of the current confinement layers. The insulation process is carried out by oxidation from the holes and oxidizing diffusion around. According to the actual need, the ion implantation process can be used after the oxidation process. The portions that are not subjected to the insulation process are the OAs at the end. Hence, the areas of the OAs are mainly determined or adjusted by controlling the number of holes, the distribution of holes or the ion implantation process such that the area of the OAs are significantly different or the areas of the OAs may be more consistent.

Without affecting the carrier confinement and optical confinement of the active layers, the insulation portions of the current confinement layers in the active region may be as small as possible, such as smaller than the insulation portions of the current confinement layers outside the active region. The less the insulation portions of the current confinement layers in the active region are, the less stress and defects in the active region it generates. The stress in the active region is smaller or there are fewer defects generated in the active region such that it is less likely to affect the reliability of a VCSEL. Preferably, the OAs of the current confinement layers are substantially circular, the OAs of the current confinement layers may be in the center regions of the current confinement layers, or the OAs of the current confinement layers correspond to each other.

The insulating region formed by the oxidation process can also improve the optical confinement of a VCSEL due to the change of the refractive index of the insulated portion of the current confinement layer and improve the performance of the VCSEL.

In some embodiments, the material of the current confinement layer has the characteristic of being easily oxidized. Preferably, the material of the current confinement layer contains aluminum or other easily oxidized materials, such as AlGaAs, AlGaAsP, AlAs, AlAsP, AlAsSb or AlAsBi.

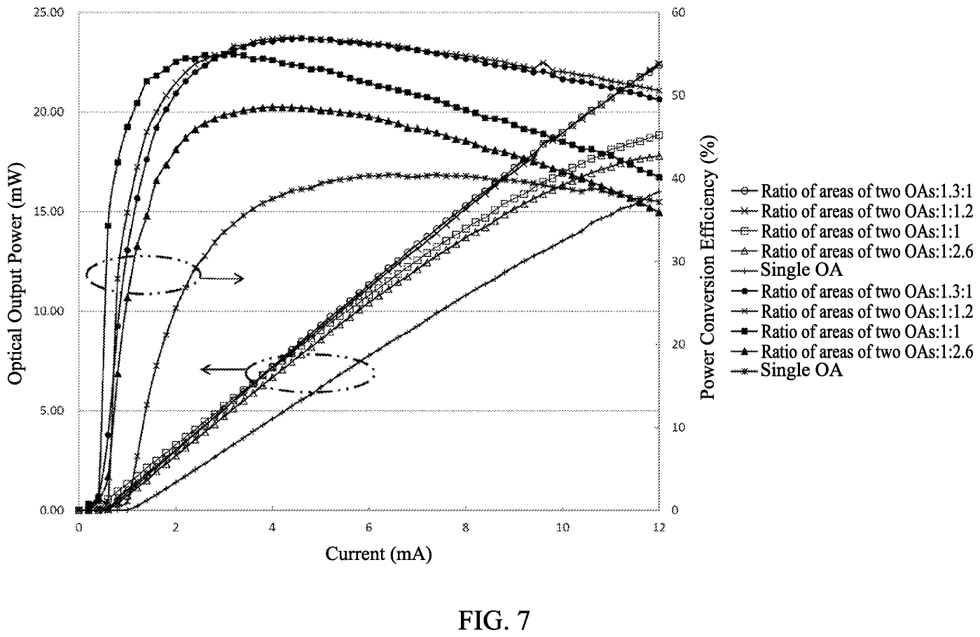

FIG. 7 shows the photoelectric characteristic of the VCSEL in which the areas of OAs of two current confinement layers at different ratios are provided and the photoelectric characteristic of the prior art in which the current confinement layer is provided only above the active region. FIG. 7 shows five substantially straight lines and five curves. The five substantially straight lines display the relationship between the VCSEL's optical output power and current, and the five curves illustrate the relationship between the PCE and current.

Referring to FIG. 7, four of five substantially straight lines and four of five curves are the results measured at room temperature based on the structures of FIGS. 1a, 1b and 1c with specific ratios of OA areas. FIG. 1a is measured with two different OA area ratios, wherein the ratios of the area of the first OA to the area of the second OA are 1:1.2 and 1:2.6, respectively. In terms of structure, the substrate of FIGS. 1a, 1b and 1c as well as the prior art are GaAs substrate, the lasing wavelengths of the VCSELs is about 940 nm, the difference between the prior art and FIG. 1a is that the prior art only provides a current confinement layer above the active region. The minimum OA diameters of FIGS. 1a, 1b and 1c as well as the prior art are about 8 μm. Specifically, the diameter of the first OA shown in FIGS. 1a and 1c is about 8 μm, the diameter of the second OA of FIG. 1b is about 8 μm, and the diameter of the prior art OA is also about 8 μm. Moreover, in the prior art and FIGS. 1a, 1b and 1c, a spacer layer is provided above and below each active layer, each current confinement layer and each tunnel junction.

Referring to FIG. 7, the optical output power and PCE at a current of 10 mA are observed. The optical output power and PCE of the prior art are the worst, only about 13.5 mW and 38.9%, respectively. Using the structure of FIG. 1a with an OA area ratio of about 1:1.2 or the structure of FIG. 1b with an OA area ratio of about 1.3:1, the increase in the optical output power and PCE of the VCSEL is the largest, where the optical output power and PCE of the VCSEL are about 19 mW and 53%, respectively. With the structure of FIG. 1c having two OAs with a diameter of about 8 μm, the optical output power and PCE of the VCSEL can reach 17 mW and 44.4%, respectively. With the structure of FIG. 1a with an OA area ratio of 1:2.6, the optical output power and PCE of the VCSEL can reach approximately 16.3 mW and 40.8%.

It should be noted that factors such as the number of active layers, the number of current confinement layers, the areas of OAs, the optical output directions or the OA types (mesa etching or non-planar etching) of a VCSEL may affect the ratios of OA areas of current confinement layers separately or simultaneously.

In principle, if the number of active layers or current confinement layers is increased, the ratios of OA areas of current confinement layers may also be increased appropriately.

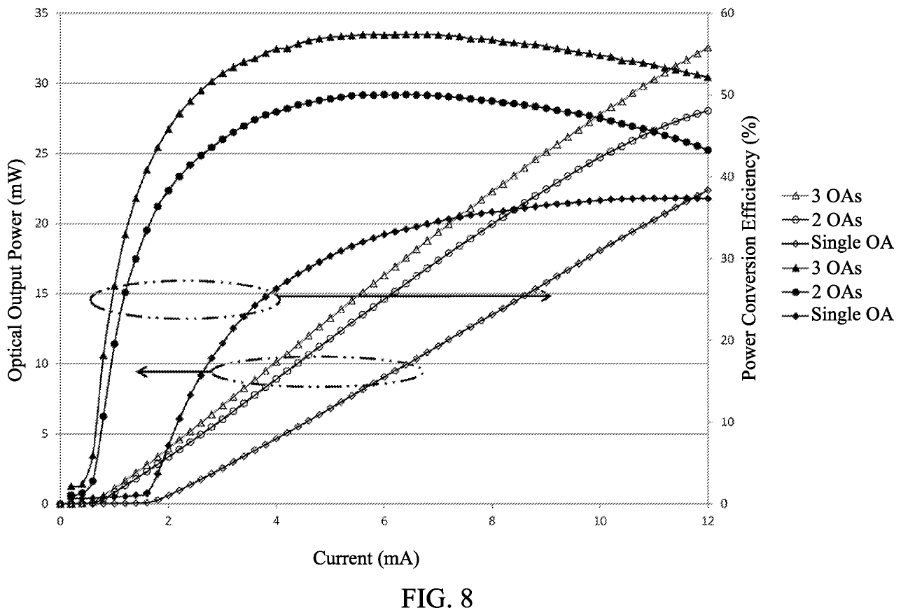

FIG. 8 shows a comparison of the photoelectric characteristic of three active layers and different numbers of current confinement layers. FIG. 8 shows three substantially straight lines and three curves. The three substantially straight lines show the relationship between the optical output power and current, and the three curves display the relationship between the PCE and current.

The three substantially straight lines and the three curves correspond to three VCSELs, respectively, wherein the substrates of three VCSELs are all GaAs substrates, and the lasing wavelength thereof are about 940 nm. The first VCSEL only has one current confinement layer disposed above the active region, and the diameter of the OA is about 8 μm, wherein the active region includes three active layers and two tunnel junctions. The second VCSEL is the VCSEL shown in FIG. 2 in which the diameter of the first OA 510 is about 8 μm. The third VCSEL is the VCSEL shown in FIG. 4a in which the diameter of the first OA is about 8 μm. In the aforementioned three VCSELs, a spacer is provided above and below each active layer, each current confinement layer and each tunnel junction.

Referring to FIG. 8, the optical output power and PCE of the VCSEL at a current of 10 mA are observed. If the current confinement layer is provided only above the active region, the optical output power and PCE of the VCSEL can only reach about 18.1 mW and 37.1%, respectively. After disposing the current confinement layer between two adjacent active layers of three active layers, the optical output power and PCE of the VCSEL can be significantly improved to about 24.7 mW and 47.1%. After the current confinement layer is provided between each two adjacent active layers of three active layers, the optical output power and PCE of the VCSEL can be greatly improved to about 27.8 mW and 54.8%.

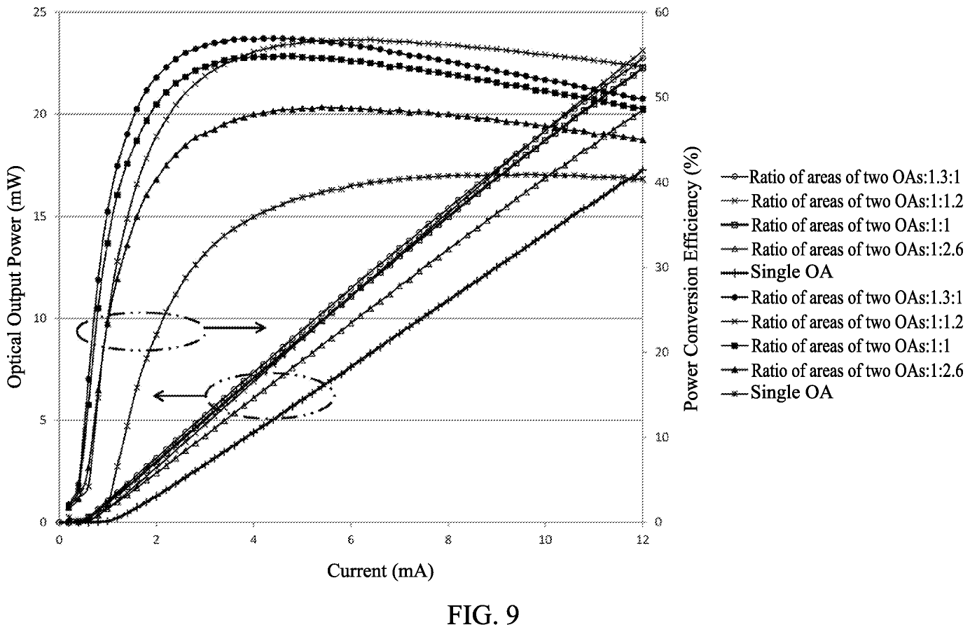

The photoelectric characteristic of FIGS. 7 and 8 are the measurement results of the top-emitting VCSELs. The photoelectric characteristic of FIG. 9 is the measurement result of the bottom-emitting VCSEL. If the optical output direction of the VCSEL is top-emitting, the total reflectivity of the upper DBR layer is less than that of the lower DBR layer. If the optical output direction of the VCSEL is bottom-emitting, the total reflectivity of the upper DBR layer is greater than that of the lower DBR layer.

FIG. 9 shows the photoelectric characteristic of the areas of OAs of the VCSEL in which two current confinement layers at different ratios are provided and the photoelectric characteristic of the prior art in which the current confinement layer is provided only above the active region. FIG. 9 illustrates five substantially straight lines and five curves. The five substantially straight lines display the relationship between the VCSEL's optical output power and current, and the five curves show the relationship between the PCE and current.

Referring to FIG. 9, four of five substantially straight lines and four of five curves are the results measured at room temperature based on the structures of FIGS. 1a, 1b and 1c with specific ratios of OA areas. FIG. 1a is measured with two different OA area ratios, wherein the ratios of the area of the first OA to the area of the second OA are 1:1.2 and 1:2.6, respectively. In terms of structure, the substrates of FIGS. 1a, 1b and 1c as well as the prior art are all GaAs substrate, the lasing wavelengths of the VCSELs of the present disclosure are all about 940 nm, the difference between the prior art and FIG. 1a is that the prior art only provides a current confinement layer above the active region. The minimum OA diameters of FIGS. 1a, 1b and 1c as well as the prior art are about 8 μm. Specifically, the diameter of the first OA shown in FIGS. 1a and 1c is about 8 μm, the diameter of the second OA of FIG. 1b is about 8 μm, and the diameter of the prior art OA is also about 8 μm. Moreover, in the prior art and FIGS. 1a, 1b and 1c, a spacer layer is provided above and below each active layer, each current confinement layer and each tunnel junction.

Referring to FIG. 9, the optical output power and PCE of the VCSEL at a current of 10 mA are observed. The optical output power and PCE of the prior art are the lowest, only about 14.1 mW and 40.8%, respectively. Using the structure of FIG. 1a with an OA area ratio of about 1:1.2 or the structure of FIG. 1b with an OA area ratio of about 1.3:1, the increase in the optical output power and PCE of the VCSEL have the most obvious improvement. The optical output power and PCE of the VCSEL are approximately 19.2 mW and 55%, respectively, and approximately 19.1 mW and 52%, respectively. With the structure of FIG. 1c having two OAs with a diameter of about 8 μm, the optical output power and PCE of the VCSEL can reach 18.7 mW and 50.7%, respectively. With the structure of FIG. 1a with an OA area ratio of 1:2.6, the optical output power and PCE of the VCSEL can reach approximately 16.8 mW and 46.6%.

Regardless of whether the optical output direction of a VCSEL is top-emitting or bottom-emitting, the optical output power, slope efficiency and PCE of the VCSEL have been improved considerably, and under the appropriate OA ratios, the optical output power, slope efficiency and PCE can be significantly improved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A vertical cavity surface emitting laser diode (VCSEL), comprising:
a multi-layer structure on a substrate, wherein the multi-layer structure comprises:
an active region, comprising a plurality of active layers, wherein a tunnel junction is provided between two active layers; and
a plurality of current confinement layers, at least comprising a first current confinement layer and a second current confinement layer, wherein the first current confinement layer at least has a first optical aperture (OA), the second current confinement layer at least has a second OA, the first OA and the second OA are uninsulated portions of each of the plurality of current confinement layers, one of the first OA and the second OA is disposed outside the active region, the other of the first OA and the second OA is disposed inside the active region, and the tunnel junction is positioned between the first OA and the second OA.

2. The VCSEL as claimed in claim 1, wherein the insulated portions of both the first current confinement layer and the second current confinement layer are made by an insulation process, and the insulation process is an oxidation process, an ion implantation process or an etching process.

3. The VCSEL as claimed in claim 1, wherein the first current confinement layer and/or the second current confinement layer is/are selected from the group consisting of AlGaAs, AlGaAsP, AlAs, AlAsP, AlAsSb and AlAsBi.

4. The VCSEL as claimed in claim 1, wherein one of the first current confinement layer and the second current confinement layer is disposed above or below the active region, and the other of the first current confinement layer and the second current confinement layer is disposed inside the active region.

5. The VCSEL as claimed in claim 1, wherein an area of the first OA is not equal to an area of the second OA.

6. The VCSEL as claimed in claim 5, wherein a ratio of the area of the first OA to the area of the second OA is approximately between 0.2 and 5.

7. The VCSEL as claimed in claim 5, wherein a ratio of the area of the first OA to the area of the second OA is approximately between 0.3 and 3.3.

8. The VCSEL as claimed in claim 5, wherein a ratio of the area of the first OA to the area of the second OA is approximately between 0.5 and 2.

9. The VCSEL as claimed in claim 1, wherein an area of the first OA is approximately equal to an area of the second OA.

10. The VCSEL as claimed in claim 9, wherein the areas of the first OA and the second OA are greater than 30 μm².

11. The VCSEL as claimed in claim 9, wherein the areas of the first OA and the second OA are greater than 40 μm².

12. The VCSEL as claimed in claim 9, wherein the areas of the first OA and the second OA are greater than 50 μm².

13. The VCSEL as claimed in claim 1, wherein the VCSEL is a top-emitting VCSEL or a bottom-emitting VCSEL.

14. A vertical cavity surface emitting laser diode (VCSEL), comprising:
a multi-layer structure on a substrate, wherein the multi-layer structure comprises:
an active region, comprising three or more active layers, wherein a tunnel junction is provided between every two adjacent ones of the active layers; and
a plurality of current confinement layers, at least comprising a first current confinement layer, a second current confinement layer and a third current confinement layer, wherein, the first current confinement layer at least has a first optical aperture (OA), the second current confinement layer at least has a second OA, the third current confinement layer at least has a third OA, the first OA, the second OA and the third OA are uninsulated portions of each of the plurality of current confinement layers, wherein one of the first OA, the second OA and the third OA is disposed outside the active region, and another of the first OA, the second OA and the third OA is disposed inside the active region, and the other of the first OA, the second OA and the third OA is disposed inside or outside the active region, the tunnel junction is positioned between the first OA and the second OA or between the second OA and the third OA.

15. The VCSEL as claimed in claim 14, wherein a number of the plurality of current confinement layers is three, four, five or more.

16. The VCSEL as claimed in claim 14, wherein a number of the plurality of current confinement layers is the same as or more than a number of active layers.

17. The VCSEL as claimed in claim 14, wherein one of the plurality of current confinement layers is disposed above or below the active region, and the others thereof are disposed inside the active region.

18. The VCSEL as claimed in claim 14, wherein when two of the first current confinement layer, the second current confinement layer and the third current confinement layer are disposed outside the active region, the active region is positioned between the two of the first current confinement layer, the second current confinement layer and the third current confinement layer.

19. The VCSEL as claimed in claim 14, wherein one of the plurality of current confinement layers is selected from the group consisting of AlGaAs, AlGaAsP, AlAs, AlAsP, AlAsSb and AlAsBi.

20. The VCSEL as claimed in claim 14, wherein areas of two of the first OA, the second OA and the third OA are not equal.

21. The VCSEL as claimed in claim 20, wherein a ratio of the areas of two of the first OA, the second OA and the third OA is approximately between 0.2 and 5.

22. The VCSEL as claimed in claim 20, wherein a ratio of the areas of two of the first OA, the second OA and the third OA is approximately between 0.3 and 3.3.

23. The VCSEL as claimed in claim 20, wherein a ratio of the areas of two of the first OA, the second OA and the third OA is approximately between 0.5 and 2.

24. The VCSEL as claimed in claim 14, wherein areas of two of the first OA, the second OA and the third OA are approximately equal.

25. The VCSEL as claimed in claim 24, wherein the areas of the first OA, the second OA and the third OA are greater than 30 μm².

26. The VCSEL as claimed in claim 24, wherein the areas of the first OA, the second OA and the third OA are greater than 40 μm².

27. The VCSEL as claimed in claim 24, wherein the areas of the first OA, the second OA and the third OA are greater than 50 μm².

28. The VCSEL as claimed in claim 14, wherein the VCSEL is a top-emitting VCSEL or a bottom-emitting VCSEL.
